(19) United States
(12) Patent Application Publication
(10) Pub. No.: US 2018/0019433 A1
(43) Pub. Date: Jan. 18, 2018

(54) MASKING FOR LIGHT EMITTING DEVICE PATTERNS

(71) Applicant: KONINKLIJKE PHILIPS N.V., Eindhoven (DE)

(72) Inventors: Holger SCHWAB, Aachen (DE); Reinhold Antonius FLEIGE, Herzogenrath (DE)

(21) Appl. No.: 15/716,660

(22) Filed: Sep. 27, 2017

Related U.S. Application Data
(63) Continuation-in-part of application No. 14/353,963, filed on Apr. 24, 2014, now Pat. No. 9,806,297.
(60) Provisional application No. 61/661,445, filed on Jun. 19, 2012.
(60) Provisional application No. 61/551,471, filed on Oct. 26, 2011.

(51) Int. Cl. H01L 51/52; H01L 27/32; H01L 51/56

(52) U.S. Cl. CPC H01L 51/5206; H01L 51/5278; H01L 51/56; H01L 27/3209; H01L 51/5221; H01L 2933/0016

(57) ABSTRACT

The present invention relates to a light emitting device with at least two active areas and a more robust method of manufacturing such a device. The method includes: depositing a first active area that emits light of a first color over an anode on a substrate; depositing an interelectrode layer through a mask overcoating the first active area; depositing a second active area, which emits light of a second color, through another mask in such a way that the active area covers and extends beyond the interelectrode; and depositing a cathode layer through a mask such that the cathode overcoats the whole second active area. Independent control of the voltages applied to the anode, the interelectrode, and the cathode enables the device to emit light of the first color, light of the second color, and light of a combination of the first and second color.

This application is a Continuation-In-Part of U.S. patent application Ser. No. 14/353,963, which is a National Stage Entry of PCT/IB12/55532, filed 12 Oct. 2012, and claims priority from U.S. applications 61/661,445, filed 19 Jun. 2012 and 61/551,471, filed 26 Oct. 2011, each of which is incorporated by reference herein.

### FIELD OF THE INVENTION

The invention relates to an organic light emitting diode (OLED) device and a method of manufacturing such a device.

### BACKGROUND OF THE INVENTION

OLED's are effectively light emitting diodes made from semiconducting organic materials. They are currently still under development and have potential application in numerous fields. First ultra-thin and low-voltage OLEDs have been described in C. W. Tang and S. A. VanSlyke, “Organic electroluminescent diodes” Appl. Phys. Lett., Vol. 51, pp. 913-915 (1987). Since then, much development has been made to improve these devices for applications in flat panel displays as well as in solid state lighting.

A typical OLED is composed of a layer of organic materials situated between two electrodes, the anode and cathode, all deposited on a substrate. During operation, a voltage is applied across the OLED such that the anode is positive with respect to the cathode. A current of electrons flows through the device from cathode to anode, as electrons are injected into the LUMO of the organic layer at the cathode and withdrawn from the HOMO at the anode. This latter process may also be described as the injection of electron holes into the HOMO. Electrostatic forces bring the electrons and the holes towards each other and they recombine forming an exciton, a bound state of the electron and hole. This happens closer to the emissive layer, because in organic semiconductors holes may be more mobile than electrons. The decay of this excited state results in a relaxation of the energy levels of the electron, accompanied by emission of radiation whose frequency is in the visible region.

Research on how to improve the device emission efficiency continues to be a major focus. In general, improved efficiency can be achieved through the use of highly efficient luminescent materials and in designing novel device structures. Higher current efficiency can be achieved by multiphoton devices consisting of stacked units of OLEDs. The current efficiency can be multiplied because of electron and hole recycling.

If OLED's with individually addressable areas are manufactured, this is done by a process in which the organic OLED material and the cathode material of each segment is deposited with individual masks in such a way, that only the areas that are supposed to emit light are coated with these materials. This leads to the situation that the mask to coat the second emissive layer area is overlapping or touching the area of the already deposited layers. This can lead to micro damages of these layers and thereby to visual damages or to short circuits. This problem is not limited to OLED devices and may as well occur in other patterned light emitting devices with layered structures.

### SUMMARY OF THE INVENTION

It is an object of the invention to provide a light emitting device and a method of manufacturing a light emitting device, by means of which an improved quality and performance of the device can be achieved.

This object is achieved by a light emitting device comprising: an anode upon a substrate, a first active layer upon the anode, an interelectrode layer that completely overlays and extends beyond the first active layer, a second active layer that overlays the interelectrode layer, a cathode that completely overlays the second active layer. As used herein, the terms anode and cathode can be reversed; that is, the anode layer and the cathode layer can alternatively be termed the cathode layer and the anode layer, respectively. The interelectrode, between the first and second active areas, may be referred to as either an anode or cathode, depending upon which active area is being referenced.

In an embodiment, the second active layer serves to completely insulate the cathode from the interelectrode layer; the first active layer emits light of a first color, the second active layer emits light of a second color. In such manner, the anode, the interelectrode and cathode can be independently controlled to selectively provide each of the first color only, the second color only, and a combination of the first color and the second color.

By completely overlaying the first and second active layers, no mask layer touches the deposited active layers. In an embodiment, the interelectrode and/or the anode are also completely overlayed, so that no mask layer touches the deposited layers. Additionally, by completely overlaying the anode and/or interelectrode, a separate insulator is not required between these layers and other subsequently deposited layers.

Moreover, in addition to an improved manufacturing yield, the homogeneity of the light emission is improved. In contrast to the case, where only the light emitting area is coated with a conductive cathode layer, a significant larger area can be coated with the cathode layer leading to reduced sheet resistance and thereby to a better current distribution.

According to a first aspect, at least two patterned active areas may be provided, wherein the interelectrode layer extends to a rim or edge of the substrate to provide a first contact portion of the light emitting device, wherein the cathode layer excludes at least a part of the first contact portion and extends to a rim of the light emitting device to provide a second contact portion, and wherein the first and second active areas can be addressed individually via the first and second contact portions and the anode. Thus, stacked active areas can be electrically addressed individually by their respective contact portions of the anode, interelectrode, and cathode layers.

According to a second aspect, two anodes are formed on the substrate, and the interelectrode layer is in contact with the second anode. Thus, light emission of the first and second active areas can be individually controlled through the first and second anodes and the cathode.

According to a third aspect which may be combined with the first aspect, the light emitting device may be an OLED device, wherein the first and second active layers are organic layers.

According to a fourth aspect which can be combined with any one of the first and second aspects, an area covered by the cathode layer is (significantly) larger than the second active area. Thereby, the sheet resistance can be reduced and current distribution can be improved.

According to a fifth aspect which can be combined with any one of the first to third aspects, the masking process may comprise shadow masking. Thereby, patterning with high flexibility—especially for organic materials—can be achieved.

According to a sixth aspect which can be combined with any one of the first to fifth aspects, the first electrode layer may be adapted to form a transparent interelectrode. In this case, the substrate may comprise a first anode and a second anode separated by an isolation area, wherein the first active area covers the first anode and extends to the isolation area, and wherein the second active area covers the interelectrode above the first anode and extends across the second anode. Thereby, a structured anode can be provided, which allows selective activation of the two active areas, wherein a mixture of emitted wavelengths is emitted in the overlapping area(s).

According to a seventh aspect which can be combined with the sixth aspect, the interelectrode may comprise a terminal for supplying electric power to vary its light transmission properties. Thus, color mixing can be controlled via a voltage applied to the interelectrode.

According to an eighth aspect which can be combined with the sixth or seventh aspect, the interelectrode may be adapted to provide a color filter characteristic. Thus, the output color can be influenced by the color characteristic of the color filter.

Further advantageous embodiments are defined below.

### BRIEF DESCRIPTION OF THE DRAWINGS

These and other aspects of the invention will be apparent from and elucidated with reference to the embodiments described hereinafter.

In the drawings:

FIG. 1 shows a top view of a first active area and an optional insulator coated onto an anode on a substrate according to an example first embodiment of the present invention;

FIG. 2 shows a top and cross-section view of an extended interelectrode layer coated onto the substrate and the first active area, according to the example first embodiment;

FIG. 3 shows a top and cross-section view of a second active area coated onto the substrate on top of the first OLED layer stack, according to the example first embodiment;

FIG. 4 shows a top and cross-section view of an extended cathode layer of a second OLED stack coated on the substrate on top of the first OLED stack, according to the example first embodiment;

FIGS. 5A-5C show alternative light emission patterns that can be achieved via the independent control of the anode, interelectrode, and cathode of the example first embodiment;

FIG. 6 shows a top and cross-section view of a first and second anodes on a second example embodiment of the present invention.

FIG. 7 shows a top and cross-section view of a first active area coated onto a substrate according to the second embodiment of the present invention;

FIG. 8 shows a top and cross-section view of a transparent interelectrode deposited onto the substrate and the first active area, according to the example second embodiment;

FIG. 9 shows a top and cross-section view of a second active area coated onto the substrate on top of the first OLED layer stack, according to the example second embodiment;

FIG. 10 shows a top and cross-section view of a cathode layer of a second OLED stack coated on the substrate on top of the first OLED stack, according to the example second embodiment;

FIGS. 11A-11D show alternative example light emission patterns that can be achieved via the independent control of the first anode, second anode, and cathode in the second embodiment.

### DETAILED DESCRIPTION OF EMBODIMENTS

Various embodiments are now described based on a stacked OLED device with at least two emitting areas and extended electrode layer(s). It is however noted that the present invention can be applied to any type of light emitting device with patterned layer-stack structure and two or more active areas. Mask deteriorations or damages are prevented by depositing structured upper layers above structured lower layers, wherein each of such upper layers is larger than its corresponding lower layer and its corresponding lower layer.

The OLED device comprises a substrate material which can be formed by a glass panel or a panel made of organic material or metal. Thus, the substrate material forms the basic structure, on which different layers are superimposed. These layers comprise at least an anode layer upon which is superimposed a plurality of different functional layers forming an active area, whereby the functional organic layers may only be shown and referred to as a single organic or luminescent layer, or active layer or area to simplify matters. These functional organic layers may comprise at least a hole injection layer, a hole transport layer, emission layers (fluorescent and/or phosphorescent emitter), in which the emission of light is realised, and at least one hole blocking layer, an electron transport layer and at least one electron injection layer, whereas the different layers are usually very thin, limited to a thickness of e.g. approximately 10 nm each. The top layer is a cathode layer, which sandwiches the different functional layers between it and the anode layer. A power supply may be connected between the anode layer and the cathode layer, and to an interelectrode between the two active areas.

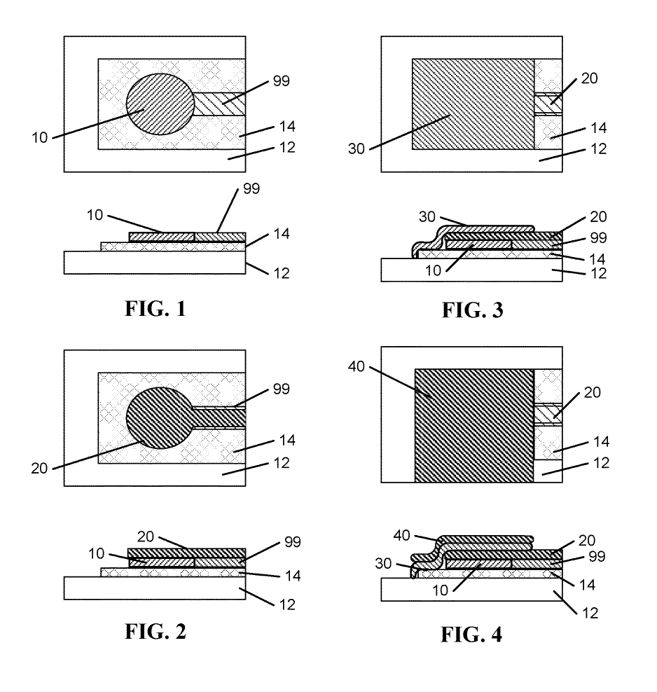

In the following, an improved manufacturing procedure for a layered OLED structure with two active areas (i.e. light emitting organic areas) according to a first embodiment of the present invention will be described with reference to FIGS. 1 to 5. Thereby, for OLED devices consisting of two or more active areas a more robust manufacturing method can be realized. The OLED device of the first embodiment comprises at least two individually addressable emitting areas with interelectrode and cathode layers, optionally providing electrical contact portions at the rim or edge of the OLED device. To prevent any shorts between anode and interelectrode layers, the anode layer may be a structured anode layer which is contacted from its backside or via a conducting path covered by an insulation layer on those areas where no active area is arranged. As another option, the anode layer may be a non-structured anode layer which is covered by an insulation layer in those areas not covered by the active area. The non-structured anode layer may be contacted from its backside or at an edge portion of the OLED device where no insulating layer is present and where the anode layer cannot get into contact with any upper interelectrode or cathode layer.

FIG. 1 shows a top and cross-section view of the OLED structure after a first step where a first organic area 10 is coated through a shadow mask onto a substrate 12 so that it partially covers a structured or non-structured anode layer 14 of the substrate 12. This may be achieved by a small-scale technique called shadow-mask evaporation where light-emitting organic molecules that make up the pixels are deposited. An alternative deposition technique may be ink-jet printing or other techniques that may combine features of shadow-mask printing and ink-jet printing to achieve high-quality OLED pixels over a large area. Furthermore, an electrically insulating area 99 may be deposited to provide insulation between the anode layer 14 and subsequently deposited conductive layers. The insulating area 99 may be omitted if the first organic area 10 covers the anode 14 so as to insulate the anode 14 from the subsequently deposited conductive layers, or the anode 14 is structured to provide a void where the subsequently deposited conductive layers are to be deposited. That is, if the anode layer 14 includes a ‘slot’ at the location of the illustrated insulator 99, exposing the substrate 12, the insulator 99 may be omitted.

FIG. 2 shows a top and cross-section view of the OLED structure after a second step wherein an interelectrode layer 20 is coated or deposited through a shadow mask onto the substrate 12 so that it covers the first organic area 10 and, if present, the insulating area 99. Hence, after this step, the interelectrode layer 20 overcoats the first organic area 10 and may extend to a contact point at the rim of the OLED device, so that a first individually addressable diode stack is formed. The interelectrode layer 20 should be somewhat smaller than the insulating area 99 to reduce the risk of any shortcuts to the anode layer. 14.

FIG. 3 shows a top and cross-section view of the OLED structure after a third step where a second organic area 30 is coated through a shadow mask onto the substrate 12, on top of the coated structure of the first active area. The second organic area 30 is deposited and the mask is made in such a way that the first OLED stack of the first active area is overcoated with the organic material of the second organic area 30 of the OLED structure. In this manner, the mask used to deposit the second organic area 30 does not contact the first OLED stack, and the second organic area 30 serves to insulate the first OLED stack from a subsequently applied cathode layer.

FIG. 4 shows a top and cross-section view of the OLED structure after a fourth step where a cathode layer 40 is coated across the second organic area 30, thereby forming a second OLED stack. The cathode layer 40 of the second diode is coated or deposited through a shadow mask such that it completely overcoats the whole second active area 30. In this manner, the mask used to deposit the cathode layer 40 does not contact the second active area 30. In this embodiment, the second contact layer 40 is enlarged to extend to the rim of the OLED structure in order to be able to electrically contact this layer by a corresponding contact portion at the rim of the OLED structure or device. Alternatively, as illustrated in FIG. 4, in this example embodiment, each of the anode 14, the interelectrode 20, and the cathode 40, is situated on the exposed surface of the formed device, thereby enabling contact at the exposed surface. That is,

Thus, at least in some areas, two OLED stacks or structures can be deposited one above the other. The upper active layer or area serves to insulate the interelectrode and cathode contact layers from each other, and the size of the cathode can be increased to provide an increased conductivity.

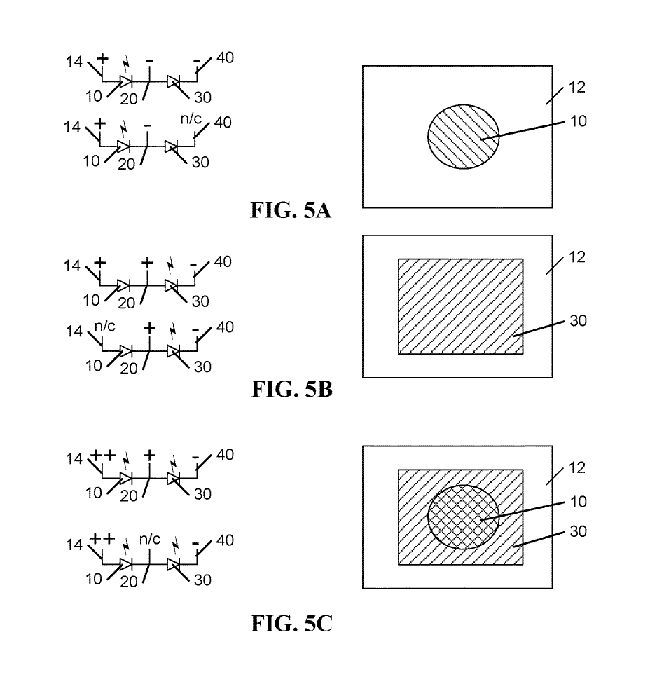

FIGS. 5A-5C show alternative light emission patterns that can be achieved via the independent control of the anode 14, interelectrode 20, and cathode 40. For ease of illustration and understanding, the symbol “−” is used to indicate a voltage that is at least a diode drop lower than the voltage indicated by the “+” symbol, and the “++” symbol is used to indicate a voltage that is at least a diode drop greater than the voltage indicated by the “+” symbol. The “n/c” annotation indicates that the node is not connected to a voltage source.

In FIG. 5A, the anode 14 receives a + voltage and the interelectrode 20 receives a − voltage. This will cause the first active area 10 to emit light of a first color. The cathode 40 is either not connected or receives a − voltage. In either case, because there is no voltage across the second active area 30, the second active area 30 will not emit light.

In FIG. 5B, the anode 14 is either not connected or receives a + voltage, and the interelectrode 20 receives a + voltage. Because there is no voltage across the first active area 10, the first active area 10 will not emit light. The cathode 40 receives a − voltage, and thus the second active area 30 emits light of a second color.

In FIG. 5C, the anode 14 receives a ++ voltage (two diode drops), the cathode 40 receives a − voltage, and the interelectrode 20 is either not connected, or receives a + voltage. In either case, this will cause the first active area 10 to emit light of a first color and the second active area 30 to emit light of a second color. Consequently, the area above the first active area 10 will appear as a combination of the first and second color, surrounded by light of the second color.

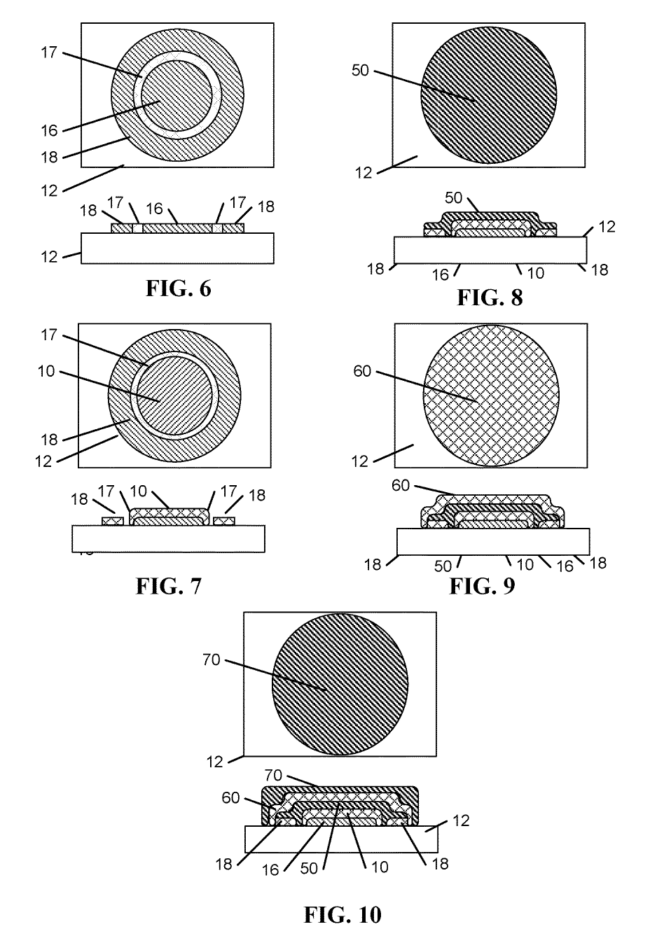

Now, a manufacturing procedure for a layered OLED structure with two active areas (i.e. light emitting organic areas) according to an example second embodiment of the present invention will be described with reference to FIGS. 6 to 11. The OLED device of the second embodiment comprises two individually emitting areas with two anodes, an interelectrode coupled to a second anode, and an upper cathode layer. FIG. 6 illustrates a top and cross-section view of a substrate 12 and two anodes 16, 18 in an example embodiment of a second embodiment of this invention. The anodes 16, 18 are isolated by an isolating area 17, which may be a simple void, or a space filled with an insulator (not shown). These anodes 16, 18 may be contacted via back contacting or by contacting strips covered by a structured isolation layer, or the anode 18 may be configured to include a slot, or gap through which a connection to anode 16 may be made.

FIG. 7 shows a top and cross-section view of the OLED structure after a first step where a first organic layer or active area 10 is coated or deposited through a shadow mask onto a substrate 12, similar to the first embodiment. This may again be achieved by a small-scale technique called shadow-mask evaporation or an alternative deposition technique such as ink-jet printing or other techniques that may combine features of shadow-mask printing and ink-jet printing to achieve high-quality OLED pixels over a large area. The first active area 10 is suitable to emit light of a certain color, for example blue, if a cathode would be present and a voltage would be applied between anode and cathode. Of particular note, the active area 10 completely covers the first anode 16, which serves to insulate the first anode 16 from all subsequently applied layers.

FIG. 8 shows a top and cross-section view of the OLED structure after a second step where a transparent interelectrode 50 is deposited or coated through a shadow mask on top of the first active area 10. Hence, after this step the interelectrode 50 completely overcoats the first active area 10, such that the mask used to form the interelectrode 50 will not contact the active area 10.

FIG. 9 shows atop and cross-section view of the OLED structure after a third step where a second organic layer or active area 60 is coated through a shadow mask onto the substrate 12, on top of the interelectrode 50. The second active area 60 is deposited and the mask is made in such a way that the first OLED stack of the first active area 10 is overcoated with the organic material of the second active area 60 of the OLED structure. The second active area 60 is thus coated onto the interelectrode 50 and at least partially over or onto the anode 18. The second active area 60 may emit light of a certain color, for example yellow, which is different from the color of the light emitted from the first active area. The second active area 60 extends over the first active area 10, and in this overlapping area, a combination of the light of the first color and the light of the second color may be emitted. Of particular note, the active area 60 completely covers the interelectrode 50, which serves to insulate the interelectrode 50 from the subsequently applied cathode layer,

FIG. 10 shows a top and cross-section view of the OLED structure after a fourth step where a cathode layer 70 of a second OLED stack of the second active area is coated across the first OLED stack. The cathode layer 70 of the second diode is coated or deposited through a shadow mask such that it extends over the active areas 10 and 60. Of particular note, the cathode completely overcoats the active area 60, such that the mask used to form the cathode layer 70 does not contact the active area 60.

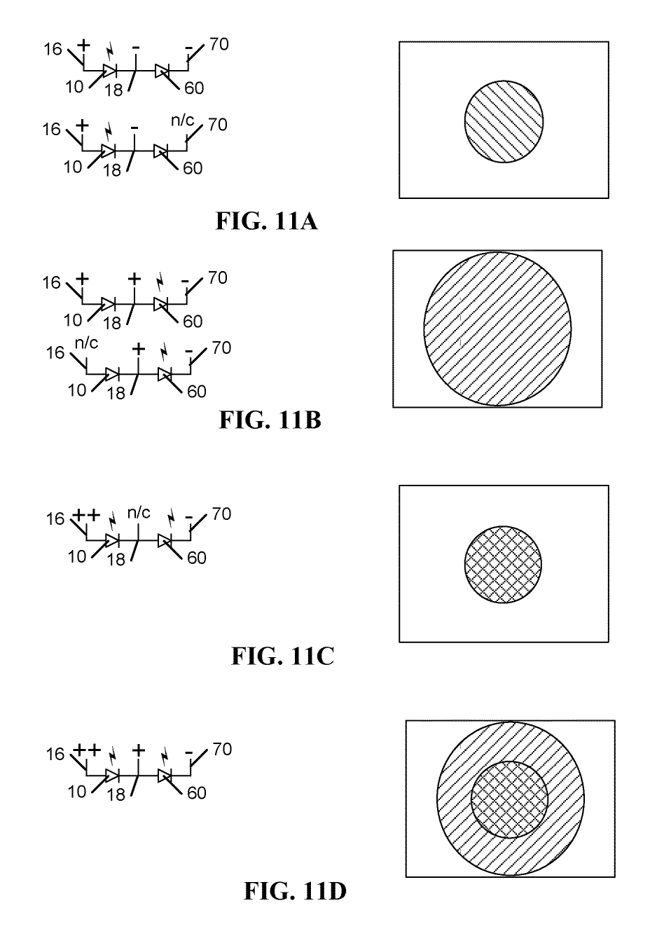

FIGS. 11A-11D show alternative light emission patterns that can be achieved via the independent control of the anode 16, anode 18, and cathode 70. As in FIG. 5, for ease of illustration and understanding, the symbol “−” is used to indicate a voltage that is at least a diode drop lower than the voltage indicated by the “+” symbol, and the “++” symbol is used to indicate a voltage that is at least a diode drop greater than the voltage indicated by the “+” symbol. The “n/c” annotation indicates that the node is not connected to a voltage source.

In FIG. 11A, the anode 16 receives a + voltage and the anode 18 receives a − voltage. This will cause the first active area 10 to emit light of a first color. The cathode 70 is either not connected or receives a − voltage. In either case, because there is no voltage across the second active area 60, the second active area 60 will not emit light.

In FIG. 11B, the anode 16 is either not connected or receives a + voltage, and the anode 18 receives a + voltage. Because there is no voltage across the first active area 10, the first active area 10 will not emit light. The cathode 70 receives a − voltage, and thus the second active area 60 emits light of a second color.

In FIG. 11C, the anode 16 receives a ++ voltage (two diode drops above −), the anode 18 is not connected, and the cathode 70 receives a − voltage. This causes current to flow from anode 16 through the first active area 10 and through the second active area 60. However, because the anode 18 is not connected, only the region of the active area 60 that is above the anode 16 will emit light. Thus, light of a combination of the first color and the second color is emitted through the region of the device that is above the first anode 16.

In FIG. 11D, the anode 16 receives a ++ voltage (two diode drops), the anode 18 receives a + voltage, and the cathode 70 receives a − voltage. This will cause the first active area 10 to emit light of a first color and the second active area 60 to emit light of a second color. Consequently, because in this case the anode 18 provides voltage to the active area 60, the area above the first anode 16 will appear as a combination of light of the first and second colors, and the area above the second anode 18 will appear as light of the second color.

To summarize, a light emitting device with at least two active areas, and a more robust method of manufacturing such a device have been described, wherein a first electrode layer is deposited through a mask overcoating an active material. A second active material is deposited through another mask in such a way that an area which covers and extends beyond the interelectrode layer is overcoated with the organic material. Then, a cathode layer is coated through a mask such that it overcoats the whole second active material.

While the invention has been illustrated and described in detail in the drawings and foregoing description, such illustration and description are to be considered illustrative or exemplary and not restrictive. The invention is not limited to the disclosed embodiment and can be used for various types of stacked light emitting device structures with three or even more stacked organic layers with intermediate interelectrode layers and resulting “overcoated pixels”. The concept could thus be generalized to three or more active areas. The size and shape of the active areas could be adapted to the efficiency of the active materials (e.g. organic or other light emitting materials) and the intended application (white light, colored light, display). As noted above, the designations/locations of anodes and cathodes could be exchanged e.g. by inverting the sequence of deposited layers. Furthermore, other variations to the disclosed embodiment can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting the scope.

1. A light emitting device comprising:
a substrate,
a first anode upon the substrate,
a first active layer upon the first anode,
an interelectrode layer that completely overlays and extends beyond the first active layer,
a second active layer that overlays the interelectrode layer, and
a cathode that completely overlays the second active layer;
wherein the second active layer serves to completely insulate the cathode from the interelectrode layer,
wherein the first anode, the first active layer, and the second anode form a first light emitting diode that emits light of a first color,
wherein the second anode, the second active layer, and the cathode form a second light emitting diode that emits light of a second color that is different from the first color, and
wherein the first anode and second anode are independently controllable to selectively provide each of the first color only, the second color only, and a combination of the first color and the second color.

2. The device of claim 1, wherein the first active layer serves to completely insulate the interelectrode layer from the first anode without the use of an insulation layer between the interelectrode layer and the first anode.

3. The device of claim 1, comprising an insulator layer that insulates the interelectrode layer from the first anode.

4. The device of claim 1, wherein at least a portion of the first anode is not covered by any of the layers, and at least a portion of the interelectrode layer is not covered by any of the layers, thereby enabling external contact to each of these portions of the first anode and the interelectrode layer.

5. The device of claim 1, wherein the interelectrode layer extends to a rim of the device to provide an external contact to the interelectrode layer.

6. The device of claim 5, wherein the first anode extends to the rim of the device to provide an external contact to the first anode, and the cathode extends to the rim of the device to provide an external contact to the cathode.

7. The device of claim 1, comprising a second anode upon the substrate and an insulation region between the first anode and the second anode, wherein the interelectrode layer is situated upon the second anode.

8. The device of claim 7, wherein the first active layer completely overlays the first anode, and serves to insulate the interelectrode layer from the first anode without the use of an insulation layer between the interelectrode layer and the first anode.

9. The device of claim 1, wherein the first and second active layers are organic layers.

10. A method of manufacturing a light emitting device, the method comprising:
providing a first anode on a substrate,
depositing a first active layer upon the first anode,
depositing an interelectrode layer that completely overlays the first active area,
depositing a second active layer upon the interelectrode layer, and
depositing a cathode layer that completely overlays the second active layer;
wherein the second active layer serves to completely insulate the cathode from the interelectrode layer,
wherein the first anode, the first active layer, and the second anode form a first light emitting diode that emits light of a first color,
wherein the second anode, the second active layer, and the cathode form a second light emitting diode that emits light of a second color that is different from the first color.

11. The method of claim 10, comprising using a shadow mask to perform the depositing of one or more of the layers.

12. The method of claim 10, comprising using ink-jet printing to perform the depositing of one or more of the layers.

13. The method of claim 10, wherein the depositing of the first active layer serves to completely insulate the interelectrode layer from the first anode without the use of an insulation layer between the interelectrode layer and the first anode.

14. The method of claim 10, wherein after depositing of all of the layers, at least a portion of the first anode is not covered by any of the layers, and at least a portion of the interelectrode layer is not covered by any of the layers, thereby enabling external contact to each of these portions of the first anode and the interelectrode layer.

15. The method of claim 10, wherein the interelectrode layer extends to a rim of the device to provide an external contact to the interelectrode layer.

16. The method of claim 15, wherein the first anode extends to the rim of the device to provide an external contact to the first anode, and the cathode extends to the rim of the device to provide an external contact to the cathode.

17. The method of claim 10, comprising providing a second anode upon the substrate and wherein the interelectrode layer is deposited upon the second anode.

18. The method of claim 17, wherein the first active layer completely overlays the first anode, and serves to insulate the interelectrode layer from the first anode without the use of an insulation layer between the interelectrode layer and the first anode.

19. The method of claim 10, wherein the first and second active layers are organic layers.

20. The method of claim 10, comprising depositing an insulator layer that insulates the interelectrode layer from the first anode.
